(19) United States
(12) Patent Application Publication
(10) Pub. No.: US 2010/0052064 A1
(43) Pub. Date: Mar. 4, 2010

(54) METHOD FOR STRAINING A SEMICONDUCTOR WAFER AND A WAFER SUBSTRATE UNIT USED THEREIN

(75) Inventors: Guo-Qiang Lo, Singapore (SG); Lakshmi Kanta Bera, Singapore (SG); Li-Hui Guo, Singapore (SG); Wei-Yip Loh, Singapore (SG); Ebin Liao, Singapore (SG); Xiaowu Zhang, Singapore (SG)

Correspondence Address: SEED INTELLECTUAL PROPERTY LAW GROUP PLLC, 701 FIFTH AVE, SUITE 5400, SEATTLE, WA, 98104, US

(73) Assignee: AGENCY FOR SCIENCE, TECHNOLOGY AND RESEARCH, Singapore (SG)

(21) Appl. No.: 12/373,881

(22) PCT Filed: Jul. 20, 2006
(86) PCT No.: PCT/SG2006/000203

§ 371 Date: Sep. 23, 2009

(51) Int. Cl. H01L 27/092; H01L 21/50

(52) U.S. Cl. 257/369; 438/118; 257/E27.062; 257/E21.499

(57) ABSTRACT

The present invention provides a method for straining a semiconductor wafer, the method comprising: providing a semiconductor wafer, the semiconductor wafer having a first wafer surface and a second wafer surface arranged substantially opposite the first wafer surface; providing a substrate, the substrate having a substrate surface; adhering the first wafer surface to the substrate surface, thereby connecting the semiconductor wafer to the substrate and forming a wafer substrate unit; heating the semiconductor wafer and the substrate to a first temperature; and cooling the wafer substrate unit to a second temperature lower than the first temperature; thereby straining and bending the semiconductor wafer. The present invention further provides a wafer substrate unit.

The present invention relates generally to the fabrication of microelectronic devices, more particularly to a method for straining a semiconductor wafer, and to a wafer substrate unit.

### BACKGROUND OF THE INVENTION

Mechanical stress engineering in the channel region of metal-oxide semiconductor field-effect transistors (MOSFETs) has attracted much attention to improve the drive current in the MOSFET devices.

Several techniques have been proposed based on engineering of the substrate, e.g., strain-Si/Si₁₋ₓGeₓ (compare: Hoyt J. L. et al: “Strained silicon MOSFET technology” in IEDM Tech. Dig., 2002, pp. 23 to 26; Takagi S. et al: “Channel structure design fabrication and carrier transport properties of strained Si/SiGe-on-insulator (strained SOI) MOSFETs” in IEDM Tech. Dig., 2003, pp. 57 to 60; Wang H. C. H. et al.: “Substrate-strained Silicon technology: Process integration” in IEDM Tech. Dig., 2003, pp. 61 to 64; and Jung J. et al: “Tradeoff between mobility and subthreshold characteristics in dual-channel heterostructure n-and p-MOSFETs” in IEEE Electron Device Lett., vol. 25, no. 8, 2004, pp. 562 to 564).

Other available techniques are based on engineering of the shallow-trench-isolation (compare: Matsumoto T. et al.: “Novel SOI wafer engineering using low stress and high mobility CMOSFET with <100> channel for embedded RF/analog applications” in IEDM Tech. Dig., 2002, pp. 663 to 666) and based on engineering of the gate electrodes (compare: Lu T. Y. et al: “Mobility enhancement in local strain channel nMOSFETs by stacked a-Si/Poly Si gate and capping nitride” in IEEE Electron Device Lett., vol. 26, no. 4, 2005, pp. 267 to 269; and Duriez B. et al.: “Gate stack optimization for 65 nm CMOS low power and high performance platform” in IEDM Tech. Dig., 2004, pp. 847 to 850).

Yet another known technique is based on engineering of an etch-stop-layer, e.g., tensile Si₃N₄ (compare: Shimizu A. et al.: “Local mechanical-stress control (LMC): A new technique for CMOS-performance enhancement” in IEDM Tech. Dig., 2001, pp. 433 to 436; Pidin S. et al.: “A novel strain enhanced CMOS architecture using selectively deposited high tensile and high compressive silicon nitride films” in IEDM Tech. Dig., 2004, pp. 213 to 216; Chen C. H. et al: “Stress memorization Technique (SMT) by selectively strained-nitride capping for sub-65 nm high-performance strained-Si device application” in VLSI Symp. Tech. Dig., 2004, pp. 56 and 57; and Ota K. et al: “Novel locally strained channel technique for high performance 55 nm CMOS” in IEDM Tech. Dig., 2002, pp. 27 to 30).

Yet another approach is based on engineering of Si₁₋ₓGeₓ or Si₁₋ₓCₓ source/drain as side-stressors (compare: Ghani T. et al.: “A 90 nm high volume manufacturing logic technology featuring novel 45 nm gate length strained silicon CMOS transistors” in IEDM Tech. Dig., 2003, pp. 978 to 980; and Ang K. W et al.: “Enhanced performance in 50 nm N-MOSFETs with silicon-carbon source/drain regions” in IEDM Tech. Dig., 2004, pp. 1069 to 1071), and based on engineering of some combinations thereof (compare: Ge C. H. et al.: “Process-strained Si (PSS) CMOS technology featuring 3-D strain engineering” in IEDM Tech. Dig., 2003, pp. 73 to 76).

Recently, techniques of post-backend applied strain have been proposed (compare: Belford R. E. et al.: “Performance-augmented CMOS using Backend uniaxial strain” in Proc. IEEE 60^{th} Dev. Res. Conf., 2002, pp. 41 and 42; Uchida K. et al.: “Experimental study of biaxial and uniaxial Strain effects on carrier mobility in bulk and ultrathin-body SCI MOSFETs” in IEDM Tech. Dig., 2004, p. 229; and Maikap S. et al.: “Mechanically strained strained-Si NMOSFETs” in IEEE Electron Device Lett., voL 25, no. 1, 2004, pp. 40 to 42). Although the stress was applied as late as the packaging step on diced samples, the improvement was evident (e.g., as high as about 20% increase in hole mobility). U.S. Pat. No. 6,514,836 discloses a method of producing strained microelectronic devices. Microelectronic devices can either be formed within a membrane, prior to straining or processed after straining. The method includes the steps of straining a membrane along at least one axis and hard pressing onto curved structures. Such techniques are advantageous, as there is no need for alteration of standard CMOS front-end integration and there is a potential for additional enhancement even on a device with pre-built-in stress.

Nevertheless, the above mentioned techniques were limited to individual die level either by pressing over a curved substrate, or “end”-/center-displaced point-bending methods. Particularly the point-bending methods may induce problems of non-uniform stress distribution because of the localized mechanical forces applied.

It is a task of further research in microelectronic engineering to find ways to add further functions to and to improve the performance of future IC microelectronic devices with new materials and device structures since the scaling of traditional field-effect transistors slows down. In particular, gate control over the channel should be retained, OFF-state drain-source leakage should be minimized, mobility/injection velocity of charge carriers should be improved, drive current for low intrinsic delay should be improved, extrinsic resistance should be reduced, and power consumption should be reduced. Accordingly, it is a challenge to improve the electronic properties of microelectronic devices. A first approach is described in Bera et al.: “The impact of uniform strain applied via bonding onto plastic substrate on MOSFET performance” in IEEE Electron Device Letters, vol 27, no. 1, January 2006.

Therefore, an objective of the present invention is to overcome the drawbacks of the above mentioned prior art, and in particular to present a method for providing uniform post-backend stress applied at the wafer level, and to simplify the application of stress to the wafer.

### SUMMARY OF THE INVENTION

According to an aspect of the present invention, a method for straining a semiconductor wafer, the method comprising: providing a semiconductor wafer, the semiconductor wafer having a first wafer surface and a second wafer surface arranged substantially opposite the first wafer surface; providing a substrate, the substrate having a substrate surface; adhering the first wafer surface to the substrate surface, thereby connecting the semiconductor wafer to the substrate and forming a wafer substrate unit; heating the semiconductor wafer and the substrate to a first temperature; and cooling the wafer substrate unit to a second temperature lower than the first temperature; thereby straining and bending the semiconductor wafer. The first wafer surface of the semiconductor wafer is usually the backside of the semiconductor wafer and the second wafer surface of the semiconductor wafer is usually the surface of the semiconductor wafer where integrated circuits are built.

According to another aspect of the present invention, a wafer substrate unit comprises a semiconductor wafer and a substrate, wherein: the semiconductor wafer has a first wafer surface, a second wafer surface arranged substantially opposite the first wafer surface; the substrate has a substrate surface; the first wafer surface is adhered to the substrate surface such that the semiconductor wafer is connected to the substrate; and the substrate strains the semiconductor wafer such that the semiconductor wafer is bent. The following remarks regarding the method of the present invention are also valid for this wafer substrate unit.

Some of the advantages provided by the method according to the present invention are as follows. First, this method can easily and simply be implemented into the backend fabrication process of IC microelectronic devices with a minimal number of process steps. Second, the performance (e.g., the mobility of charge carriers like electrons and holes) of these microelectronic devices processed according to the method of this invention can be improved. Third, this improvement of the performance of the microelectronic devices is uniform across the whole semiconductor wafer. Due to the minimal number of process steps needed to perform the method of the present invention, the production costs for correspondingly produced microelectronic devices are lower than in the prior art. In particular, the present invention provides bending of the semiconductor wafer and the strain applied for bending can be tuned directional and with respect to the magnitude as required.

Contrary to the prior art where at the backend of the fabrication the application of stress to a wafer is minimized for avoiding wafer cracking, the present invention deliberately induces strain onto the semiconductor wafer by the substrate to obtain a bent semiconductor wafer, and, thus, to improve charge carrier mobility in the channel between source and drain. Consequently, the present invention improves the electrical properties of IC microelectronic devices arranged on the semiconductor wafer processed according to the method of the present invention.

It is pointed out that the substrate used in the method according to the present invention acts as strainer onto the semiconductor wafer and, thus, onto each of the microelectronic devices. During separation of the microelectronic devices, the substrate is also separated into substrate parts. Therefore, after separation of the microelectronic devices, each substrate part is connected to one of the microelectronic devices and still strains this microelectronic device. In one embodiment, the resultant semiconductor wafer is dependent on the initial strain on the substrate. Depending on whether the initial strain on the substrate is tensile or compressive, the resultant semiconductor wafer after bonding can also be tensile or compressive strained.

In another embodiment, the semiconductor wafer and the substrate have different thermal expansion coefficients. The semiconductor wafer has a first thermal expansion coefficient and the substrate has a second thermal expansion coefficient. Depending on whether the second thermal expansion coefficient is greater than the first thermal expansion coefficient or vice versa, the semiconductor wafer can be tensile strained or compressive strained. Therefore, the method of the present application may further comprise using materials for the semiconductor wafer and the substrate such that the second thermal expansion coefficient is greater than the first thermal expansion coefficient or vice versa. Further, according to the present invention the substrate may strain the semiconductor wafer across the whole first wafer surface of the semiconductor wafer in an uniaxial direction or even in a biaxial direction.

The semiconductor wafer may be formed of any suitable semiconductor materials, such as silicon (Si), poly-silicon, gallium arsenide (GaAs), germanium (Ge) or silicon-germanium (SiGe). The substrate may be formed of any suitable material that can be adhered and while bending induces strain. In exemplary embodiments, such a material may be selected from glass, fiberglass (FR-4), a laminate of glass reinforced hydrocarbon and ceramic (such as “RO4***” series that are available from Roger Corporation, Connecticut, U.S.A.), polymeric material such as polytetrafluoroethylene (PTFE), silicon nitride (Si₃N₄), titanium nitride (TiN) or aluminum (Al), to name only a few suitable substrate materials. The substrate materials may be tensile strained or compressive strained by nature but can also vary with the manner of deposition or treatment. As an illustrative example in this regard, silicon nitride (Si₃N₄) can be tensile or compressive depending on the manner of deposition and deposition conditions. Typical plasma-enhanced chemical vapor deposition (PECVD) Si₃N₄ is based on low-frequency biasing power. The higher the biasing power means that a higher field is applied onto the ions. This can cause a higher bombardment of ions on the Si₃N₄ film and result in the Si₃N₄ film becoming more dense or compressive. Reducing the biasing power can thereby result in the Si₃N₄ film becoming less dense or tensile. As another illustrative example in this regard, plasma vapor deposition (PVD) TiN can also be rendered tensile or compressive depending on the manner of deposition and deposition conditions. The higher the temperature during deposition, the more tensile TiN becomes. For a further example of a tensile material that may be used here is aluminum (Al), which can either be deposited on or aligned with the semiconductor wafer.

Further, the semiconductor wafer may be provided with a diameter of between about 20.32 cm (8 inches) to 30.38 cm (12 inches) and may have a particular diameter of 20.32 cm (8 inches) and 30.38 cm (12 inches) respectively. Of course, semiconductor wafers of any other suitable dimensions, for example 4 inches or 6 inches can also be used. The semiconductor wafer can be a silicon wafer or Silicon on Insulator (SOI) wafer, but not so limited.

According to one embodiment of the present invention, the semiconductor wafer and the substrate may be heated individually to a first temperature. After the semiconductor wafer and the substrate have been heated to the first temperature, the first wafer surface of the semiconductor wafer is adhered to the substrate surface by bonding. For this purpose, the semiconductor wafer and the substrate can be heated to any suitable temperature at any suitable rate of heating depending on the chosen material for the semiconductor wafer and the substrate. For example, this bonding is carried out after raising the temperature of the semiconductor wafer and of the substrate, for example FR-4 by heating at a heating rate of about 1° C. per minute to a value within the range of about 120° C. to 400° C., in particular to about 160° C. This temperature can then be maintained for any suitable time period of about 10 minutes to 40 minutes, such as about 20 minutes. The first wafer surface is bonded to the substrate surface by applying a suitable pressure force of for example, about 0.064 MPa for a suitable time period. This time period can be about 50 minutes. After applying the pressure force, the temperature is further maintained for a suitable time period of about 10 minutes to 40 minutes, such as for about 20 minutes. Then, the obtained wafer substrate unit is actively cooled at a suitable cooling rate of about 1° C. per minute down to a second temperature of about 50° C., before the wafer substrate unit passively cools down to ambient temperature. Ambient temperature can be about 15° C. to about 25° C. or to about 40° C. but any suitable temperature can also be used. In this respect it is noted that the formulation “active cooling” has the meaning of cooling by applying an external cooling means to the wafer substrate unit, and that the formulation “passive cooling” has the meaning of internal cooling by exposing the wafer substrate unit to the ambient such that the temperature of the wafer substrate unit over time converges to the ambient temperature. The respective heating and cooling protocol can be determined empirically. The process conditions can be optimized according to the selected materials and is not so limited.

In another embodiment, the semiconductor wafer and the substrate can be bonded together to form a wafer substrate unit before heating to a first temperature. A suitable pressure force is then applied to the wafer substrate unit for a suitable time period. After applying the pressure force, the temperature is maintained for a further suitable time period before being cooled at a suitable cooling rate to a suitable second temperature. In this regard, it does not matter if the semiconductor wafer and substrate is being heated individually or heated after they have been bonded. All the temperatures and durations of heating and cooling can be interpreted by a person skilled in the art.

According to another embodiment of the present invention, the substrate is provided together with adhering the first wafer surface to the substrate surface in a single step by commonly depositing substrate material onto the first wafer surface. The substrate material may be deposited onto the first wafer surface by chemical vapor deposition (CVD) or by sputtering. In one embodiment, the substrate material is deposited by PECVD. For FR-4 substrate material, the substrate material deposition may be carried out after raising the temperature of the semiconductor wafer to a suitable temperature by heating at a suitable heating rate, for example by heating at about 1° C. per minute to a value within the range of about 120° C. and 400° C., in particular of about 160° C. For Si₃N₄ or TiN substrate material, the temperature can be raised to a value within the range of about 200° C. and 400° C. The temperature can then be maintained for a suitable period of time, such as about 1 minute to about 30 minutes, for example about 20 minutes but is not so limited thereto. The heated first wafer surface is then covered with heated substrate material. After deposition of the substrate material, the temperature may be maintained for a further 20 minutes but not so limited. Then, the obtained wafer substrate unit may be actively cooled at a cooling rate of for example about 1° C. per minute down to a temperature of about 50° C. Thereafter, the wafer substrate unit passively cools down to about ambient temperature.

According to the present invention, the semiconductor wafer comprises a plurality of microelectronic devices at the second wafer surface of the semiconductor wafer. These microelectronic devices may comprise metal-oxide semiconductor field-effect transistors, i.e. at least one N-MOSFET and/or P-MOSFET. Each metal-oxide semiconductor field-effect transistor comprises a source, a drain and a gate, wherein the gate is arranged between the source and the drain. The semiconductor wafer is strained either in a direction perpendicular to source-drain or in a direction parallel to gate or a combination thereof. The semiconductor wafer may also comprise a plurality of optoelectronics devices. The behavior of the optoelectronic devices on the semiconductor wafer can also be modulated by the method of straining the semiconductor wafer.

In one embodiment, the semiconductor wafer can be thinned before straining the semiconductor wafer. In one illustrative embodiment, the semiconductor wafer can be thinned to any suitable thickness of between but not limited to 100 μm to 400 μm, for example to a thickness of about 200 μm. The thinning of the semiconductor wafer can be performed by any suitable process such as but not limited to mechanical grinding, chemical mechanical polishing (CMP), wet etching and atmospheric downstream plasma (ADP) dry chemical etching (DCE).

In one embodiment of the method of the present invention, the substrate is patterned at the substrate surface before the semiconductor wafer is adhered to the substrate. The substrate can be wet-etched after production of the substrate, or shadow masked during the production of the substrate. For example, shadow masking during the production of the substrate may be carried out by sputtering substrate material through a shadow mask. For adjusting the density of the substrate material and, thus, for obtaining a tensile strained substrate or a compressive strained substrate, the substrate material can be sputtered at different powers. Further, the substrate may be patterned by one- or two-dimensionally patterning the substrate stripe alike.

The present invention as shortly described above will be more fully understood and further features and advantages of the present invention will become clear in view of the following description, drawings and non-limiting examples.

### BRIEF DESCRIPTION OF THE DRAWINGS

In order to understand the present invention and to demonstrate how the present invention may be carried out in practice, illustrative embodiments will now be described by way of non-limiting examples only, with reference to the accompanying drawings. Therein, like reference numerals denote like objects. In the accompanying drawings:

FIG. 1 shows a cross-section through a wafer substrate unit produced by a method according to a first embodiment of the present invention, wherein a semiconductor wafer comprising three microelectronic devices is strained by a substrate;

FIG. 2a shows a first step of the method for straining the wafer substrate unit according to the first embodiment of the present invention;

FIG. 2b shows a second step of the method for straining the wafer substrate unit according to the first embodiment of the present invention;

FIG. 2c shows a third step of the method for straining the wafer substrate unit according to the first embodiment of the present invention;

FIG. 2d shows a fourth step of the method for straining the wafer substrate unit according to the first embodiment of the present invention together with an enlarged part of the final wafer substrate unit;

FIG. 3a shows a cross-section through a wafer substrate unit during production by a method according to a second embodiment of the present invention, wherein a semiconductor wafer comprising three microelectronic devices is covered by a substrate;

FIG. 3b shows an enlarged cross-section through the wafer substrate unit produced by the method according to the second embodiment of the present invention;

FIG. 4a shows a photograph of a wafer substrate unit produced by the method according to the first or second embodiment of the present invention and strained in horizontal direction;

FIG. 4b shows a photograph of a wafer substrate unit produced by the method according to the first or second embodiment of the present invention and strained in vertical direction;

FIG. 5 shows a simulation of the warpage of a wafer substrate unit strained according to the present invention;

FIG. 6a shows a simulation of the strain contour of a wafer substrate unit strained according to the present invention;

FIG. 6b shows a simulation of the stress contour of a wafer substrate unit strained according to the present invention;

FIG. 7 shows a photograph of a wafer substrate unit biaxially strained according to the present invention;

FIG. 8 shows a schematic top view onto a microelectronic device arranged on a wafer substrate unit strained according to the present invention;

FIG. 9 shows a diagram with two graphs of simulated strain, one graph belonging to the values of a wafer substrate unit strained according to the present invention and, for comparison, one graph belonging to the values of a wafer substrate unit strained according to the prior art;

FIG. 10a shows a graphical diagram of drain current vs. drain voltage for an N-MOSFET arranged on a wafer substrate unit according to the present invention with and without strain;

FIG. 10b shows a graphical diagram of drain current vs. drain voltage for a P-MOSFET arranged on a wafer substrate unit according to the present invention with and without strain;

FIG. 11a shows a graphical diagram of improvement of saturated drain current vs. gate length for an N-MOSFET arranged on a wafer substrate unit strained according to the present invention;

FIG. 11b shows a graphical diagram of improvement of saturated drain current vs. gate width for N-MOSFETs with two different gate lengths arranged on a wafer substrate unit strained according to the present invention; and

FIG. 12 shows a graphical diagram of improvement of saturated drain current vs. position on the wafer for N-MOSFETs with two different gate lengths and widths arranged on a wafer substrate unit strained according to the present invention.

FIG. 13a shows a graphical diagram of enhancement of saturated drain current vs. gate length for an P-MOSFET arranged on a wafer substrate unit strained according to the present invention;

FIG. 13b shows a graphical diagram of enhancement of linear mode drain current vs. gate length for an P-MOSFET arranged on a wafer substrate unit strained according to the present invention;

FIG. 14a shows a schematic top view of a semiconductor wafer patterned according to the present invention.

FIG. 14b shows a schematic top view of a substrate patterned according to the present invention.

### DETAILED DESCRIPTION OF EXEMPLARY EMBODIMENTS

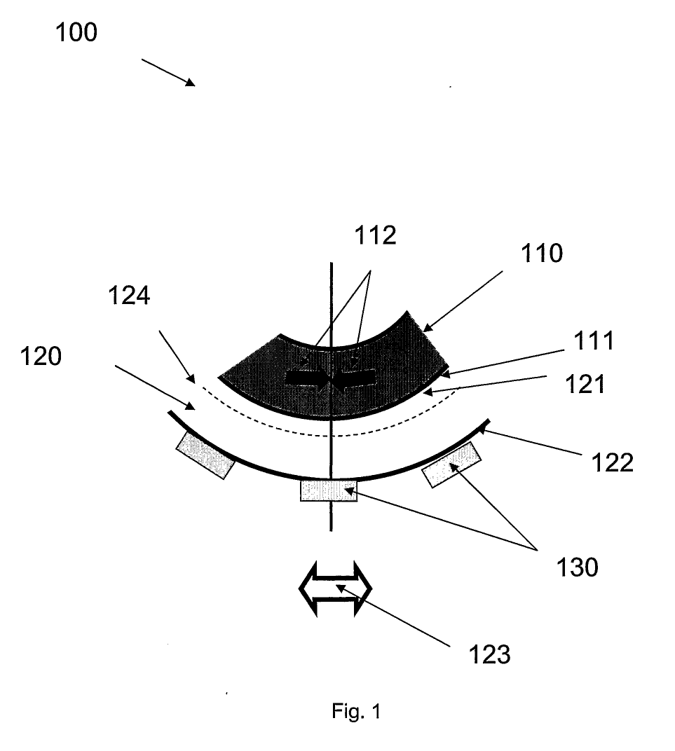

A cross-section through a wafer substrate unit 100 at ambient temperature (also referred to as “room temperature”) is shown in FIG. 1 which has been produced by a method according to a first embodiment of the present invention. The wafer substrate unit 100 comprises a substrate 110, a semiconductor wafer 120, and a plurality of microelectronic devices 130. The substrate 110 comprises a substrate surface 111, and the semiconductor wafer 120 comprises a first wafer surface 121 and a second wafer surface 122 arranged opposite the first wafer surface 121. The substrate 110 contacts the semiconductor wafer 120 so that the substrate surface 111 and the first wafer surface 121 are congruent. The plurality of microelectronic devices 130 is arranged on the second wafer surface 122, i.e. on the opposite site of the semiconductor wafer 120 with respect to the substrate 110. It is preferred to use silicon (Si) as material for the semiconductor wafer 120, and to use composite of a resin epoxy reinforced with a woven fiberglass (FR-4) as material for the substrate 110. Therefore, the semiconductor wafer 120 has a thermal expansion coefficient of about 2.6×10⁻⁶ per ° C. and the substrate 110 has a thermal expansion coefficient of about 15×10⁻⁶ per ° C. Nevertheless, any other suitable materials can be used for the semiconductor wafer 120 and for the substrate 110. For example, a laminate of glass reinforced hydrocarbon and ceramic (generally known as “RO4***” series), polymeric material such as polytetrafluoroethylene (PTFE, generally known as “Teflon”), silicon nitride (Si₃N₄), or titanium nitride (TiN) can be used as material for the substrate 110. Further, the R04*** series high frequency laminates like R04000, R04350 and R04003 are materials manufactured by Rogers Corporation, Connecticut, U.S.A. In this regard, however, any suitable laminates can also be used.

The wafer substrate unit 100 is strained in that the substrate 110 was compressed by large shrinkage and is now under the influence of compressive strain as indicated by two arrows 112 facing each other, whereas the semiconductor wafer 120 stands under the influence of tensile strain as indicated by two arrows 123 oriented in opposite directions. Therefore, the wafer substrate unit 100 is in a bent condition. There exists a strain-neutral plane 124 between the compressive strain part and the tensile strain part of the wafer substrate unit 100, the strain-neutral plane 124 existing inside the semiconductor wafer 120. In consequence, each of the plurality of microelectronic devices 130 also stands under the influence of tensile strain. It is preferred to use metal-oxide semiconductor field-effect transistors (MOSFET) as microelectronic devices 130. However, the person skilled in the art will know that the microelectronic devices 130 are not limited to MOSFETs, but can also comprise any other suitable integrated circuits, e.g., optical modulators, Schottky-barriers, bipolar transistors, etc.

It has to be noted that the bending radius of the wafer substrate unit 100 can be controlled via the thickness of the substrate 110. Preferably, the thickness of the substrate 110 is about 200 μm. Further, according to the present invention, the semiconductor wafer 120 has a diameter of about 20.32 cm (8 inches).

With respect to the composite material of resin epoxy reinforced with a woven fiberglass (FR-4) which is used for the substrate 110 in an illustrative example of the first embodiment of the present invention, it is noted that this material is an anisotropic material causing orthotropic elasticity. Due to the anisotropy of this material, the elastic modulus E, the Poisson's ratio ν, and the thermal expansion coefficient ε are different in x-, y- and z-directions. This material has an elastic modulus in x- and y-directions of Eₓ=E_{y}=22 GPa and in z-direction of E_{z}=10 GPa, a thermal expansion coefficient in x-direction of TECₓ=15 ppm/° C., in y-direction of TEC_{y}=30 ppm/° C., and in z-direction of TEC_{z}=70 ppm/° C., and a Poisson's ratio of ν_{xy}=ν_{yz}=0.28 and ν_{xz}=0.11. In this respect, the following equation (1) is generally valid for this material:

νᵢⱼ/Eᵢ=νⱼᵢ/Eⱼ. (1)

The following equation (2) can be used for calculating the strain tensor εᵢⱼ:

$$\{ \begin{matrix}{ɛ}_{xx} \\ {ɛ}_{yy} \\ {ɛ}_{zz} \\ {ɛ}_{xy} \\ {ɛ}_{xz} \\ {ɛ}_{yz}\end{matrix} \} = [ \begin{matrix}1 / {E}_{x} & - {v}_{yx} / {E}_{y} & - {v}_{zx} / {E}_{z} & 0 & 0 & 0 \\ - {v}_{xy} / {E}_{x} & 1 / {E}_{y} & - {v}_{zy} / {E}_{z} & 0 & 0 & 0 \\ - {v}_{xz} / {E}_{1} & - {v}_{yz} / {E}_{2} & 1 / {E}_{z} & 0 & 0 & 0 \\ 0 & 0 & 0 & 1 / 2 {G}_{xy} & 0 & 0 \\ 0 & 0 & 0 & 0 & 1 / 2 {G}_{xz} & 0 \\ 0 & 0 & 0 & 0 & 0 & 1 / 2 {G}_{yz}\end{matrix} ] \{ \begin{matrix}{σ}_{xx} \\ {σ}_{yy} \\ {σ}_{zz} \\ {σ}_{xy} \\ {σ}_{xz} \\ {σ}_{yz}\end{matrix} \} . \qquad ( 2 )$$

In the equation (2), σᵢⱼ is the stress tensor, Gᵢⱼ is the shear modulus tensor, and νᵢⱼ is the Poisson's ratio tensor, where i, j can be any one of x, y or z.

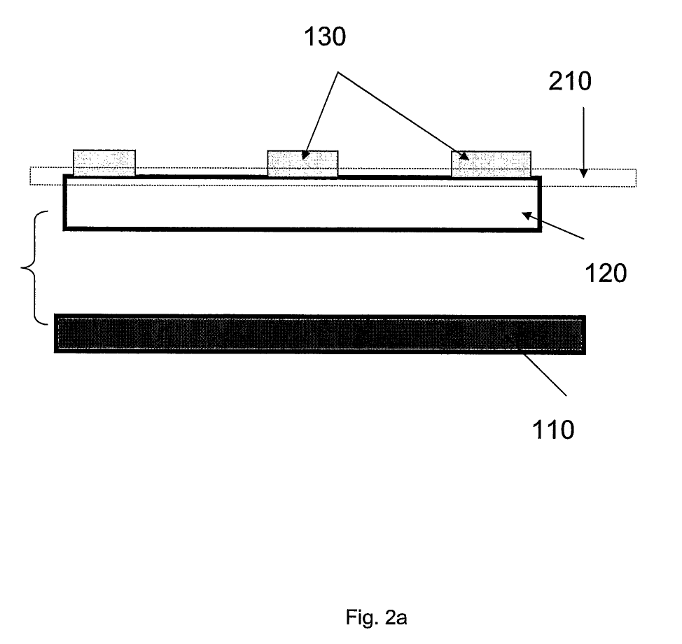

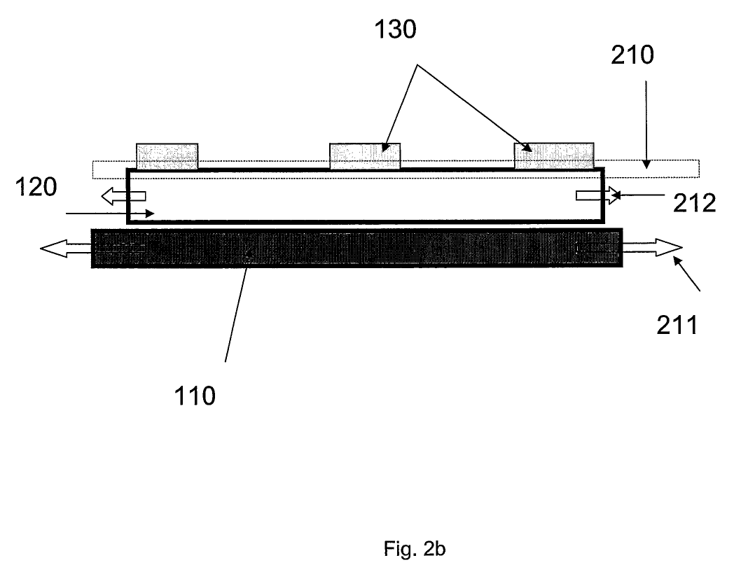

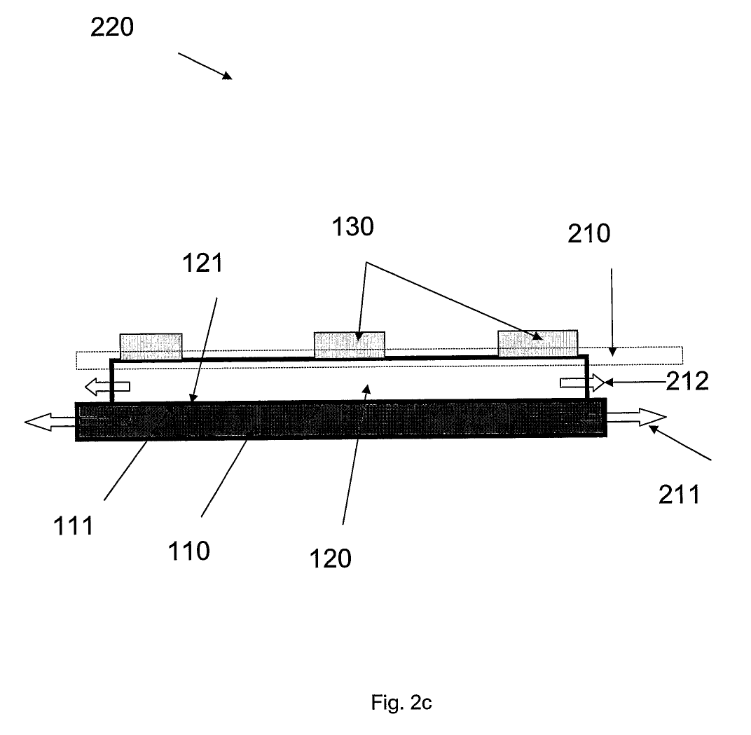

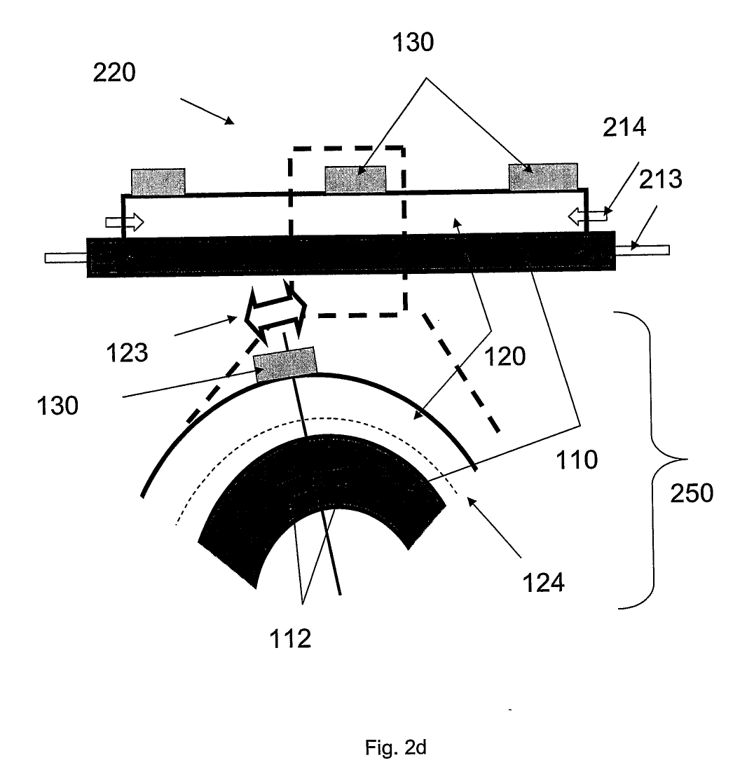

In the following, a method for producing the strained wafer semiconductor unit 100, and therefore for straining the semiconductor wafer 120, according to a first embodiment of the present invention is described in detail with respect to FIG. 2a to FIG. 2d.

The method according to the first embodiment of the present invention as illustrated in FIG. 2a starts at ambient temperature with the substrate 110 having the desired thickness and the semiconductor wafer 120 being completely processed by commonly known microelectronic semiconductor processing techniques which are known to a person of average skilled in the art. The dotted line 210 represents the active layer comprising the microelectronic devices 130, e.g. transistors, integrated at the semiconductor wafer 120. Besides the active layer 210, the semiconductor wafer 120 may comprise further layers, e.g., connection layers comprising interconnects and track conductors.

According to the illustrative example of the method of the first embodiment of the present invention in FIG. 2b, the substrate 110 and the semiconductor wafer 120 together with the microelectronic devices 130 are heated at a heating rate of about 1° C. per minute to a temperature of about 160° C. If necessary, the heating may also reach temperatures up to about 200° C. This temperature is maintained for about 20 minutes. During this heating and maintaining of this temperature, the substrate 110 and the semiconductor wafer 120 expand. In one illustrative example, the substrate 110 has a thermal expansion coefficient which is greater than the thermal expansion coefficient of the semiconductor wafer 120; therefore the substrate 110 expands more than the semiconductor wafer 120. FIG. 2b shows a step of the method according to the first embodiment of the present invention where the expanded semiconductor wafer 120 is loosely adhered to the expanded substrate 110. The expansion of the substrate 110 is indicated by the substrate expansion arrows 211, and the expansion of the semiconductor wafer 120 is indicated by the wafer expansion arrows 212. Since the expansion of the substrate 110 is greater than that of the semiconductor wafer 120, the substrate expansion arrows 211 are shown bigger than the wafer expansion arrows 212.

Next, in this illustrative example in FIG. 2c, the expanded semiconductor wafer 120 is adhered by means of a pressure force of about 0.064 MPa to the expanded substrate 110. The pressure force is applied for about 50 minutes at the above mentioned temperature of about 160° C. In particular, the first wafer surface 121 is adhered to the substrate surface 111. By applying this pressure force under the given conditions, the expanded semiconductor wafer 120 is bonded to the expanded substrate 110 and forms an expanded wafer substrate unit 220. The situation during and shortly after this bonding is shown in FIG. 2c. Therein, the substrate expansion arrows 211 and the wafer expansion arrows 212 are still shown since the expanded wafer substrate unit 220 is still in its heated condition. After removal of the pressure force, the temperature of about 160° C. is maintained for further 20 minutes on the expanded wafer substrate unit 220.

After these further 20 minutes, the temperature is actively cooled down in the illustrative example in FIG. 2d at a cooling rate of about 1° C. per minute to a temperature of about 50° C. During this cooling step, the expanded wafer substrate unit 220 contracts. Due to the different thermal expansion coefficients, the substrate 110 contracts more than the semiconductor wafer 120 leading to stress inside the wafer substrate unit 220. This different contraction is expressed by substrate contraction arrows 213 and wafer contraction arrows 214 having a different size in FIG. 2d. The stress inside the wafer substrate unit 220 results in compression strain in the substrate 110 and in tensile strain in the semiconductor wafer 120 leading to a bending of the wafer substrate unit 220. However in another illustrative embodiment, the bending of the wafer substrate unit 220 can also be due to the initial strain on the substrate 110 rather than due to the different thermal expansion coefficients.

After this active cooling of the wafer substrate unit 220 down to a temperature of about 50° C., the wafer substrate unit 220 further passively cools down by itself to ambient temperature. The cooled down final wafer substrate unit 220 together with an enlarged part 250 of the final wafer substrate unit 220 are shown in FIG. 2d. It is noted that the bending effect onto the wafer substrate unit 220 is shown only qualitatively in FIG. 2d, but not quantitatively and not true to scale. The real bending radius results at least from the difference in the thermal expansion coefficients of the materials used for the substrate 110 and the semiconductor wafer 120, from the thickness of the substrate 110, from the thickness of the semiconductor wafer 120 or from the type of substrate used as the substrate can be strained. Since the whole substrate 110 and the whole semiconductor wafer 120 are affected by the above described method of the first embodiment of the present invention, biaxial tensile strain can be achieved for the complete area where the substrate 110 is bonded to the semiconductor wafer 120.

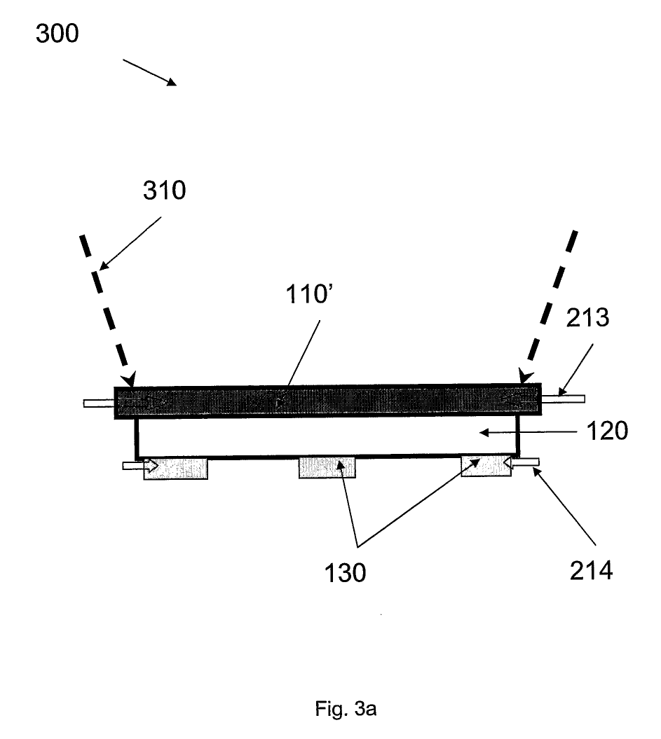

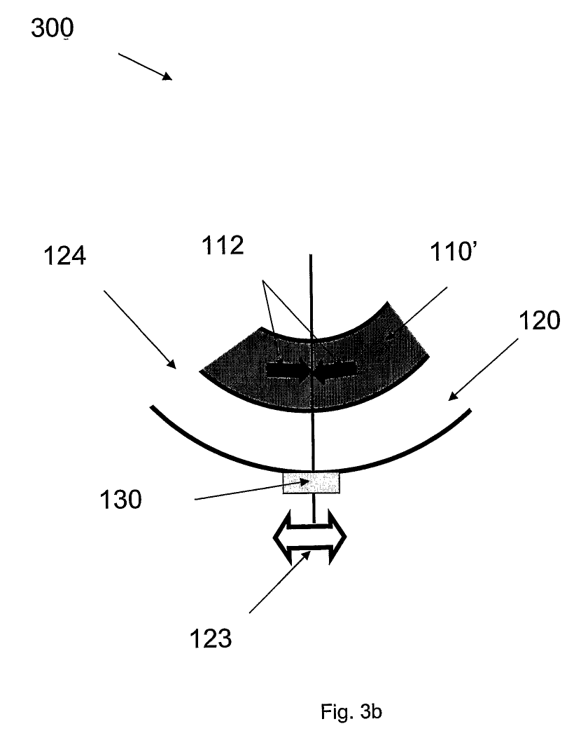

A cross-section through a wafer substrate unit 300 during production by an illustrative example of the method according to a second embodiment of the present invention is shown in FIG. 3a. This wafer substrate unit 300 comprises a semiconductor wafer 120 having three microelectronic devices 130 and being covered by a substrate 110′. After heating the semiconductor wafer 120 to a temperature of about 160° C. in a similar manner like in the example of the first embodiment of the present invention, the substrate 110′ has been formed directly on the heated semiconductor wafer 120 by plasma-enhanced chemical vapor deposition which is indicated by two deposition arrows 310. Due to the deposition process, the substrate 110′ in this embodiment may comprise silicon nitride (Si₃N₄) or titanium nitride (TiN). For depositing the substrate material, the plasma-enhanced chemical vapor deposition is carried out at a current of between about 4 kA and about 8 kA. The heated wafer substrate unit 300 is then cooled down to ambient temperature in a manner already described above with respect to the first embodiment of the present invention so that a description thereof is omitted here.

Like in the first embodiment of the present invention, also in the illustrative example of the second embodiment of the present invention, the initial strain on the substrate 110′ or the different thermal expansion coefficients of the substrate 110′ and of the semiconductor wafer 120 result in stress affecting on the wafer substrate unit 300 resulting in a bent wafer substrate unit 300. The stress level is tuned, e.g., by adjustment of the high-frequency bias power, of the temperature, and/or of the sputtering power. An enlarged cross-section through the wafer substrate unit 300 produced by the method according to the second embodiment of the present invention is shown in FIG. 3b. When comparing FIG. 3b and FIG. 2d it can be seen that the final wafer substrate units 100 and 300 are identical in their structure although they have been produced differently. In the second embodiment of the present invention, the thickness of the substrate 110′ can be adjusted for example, either by depositing a thicker substrate and, then, thinning this thicker substrate to the desired thickness, or by depositing substrate material as much as necessary for the desired thickness.

In both the first and second embodiment of the present invention, it is possible to thin the semiconductor wafer 120 before combining it with the substrate 110 or 110′ to the wafer substrate unit 100 or 300. This thinning is a commonly known process that is within the knowledge of the average skilled person skilled in the art.

If it is desired to only uniaxially strain the wafer substrate unit, the present invention provides the possibility to either use an additional, textured glue layer between the substrate and the semiconductor wafer of the first embodiment of the present invention. It is also possible to texture the substrate directly, i.e., to provide an appropriate pattern (e.g., a plurality of parallel lines like in an optical grating) to the wafer substrate unit. The present invention also provides the possibility to make use of a textured shadow mask during depositing substrate material according to the second embodiment of the present invention. This texturing (of the glue layer, the substrate or the shadow mask) can be carried out by providing a stripe alike wrap oriented mainly in one direction. If this texturing is carried out in cross-hatch directions, the biaxial strain to the wafer substrate unit can be enhanced. The texturing may result in cavities having a depth of up to about 200 μm.

Wafer substrate units have been successfully built according to the invention with the following data: thickness of the semiconductor wafer in the range between about 170 μm and about 700 μm; N- and P-MOSFETs with a gate width of about 10 μm and gate lengths in the range of about 10 μm to about 65 nm; thickness of the textured glue layer at about 60 μm; thickness of the FR-4 substrate at about 0.1 mm, at about 0.4 mm, and at about 0.8 mm. A 0.2 mm thick R04003 substrate showed a more uniform bending behavior than any of the FR-4 substrates.

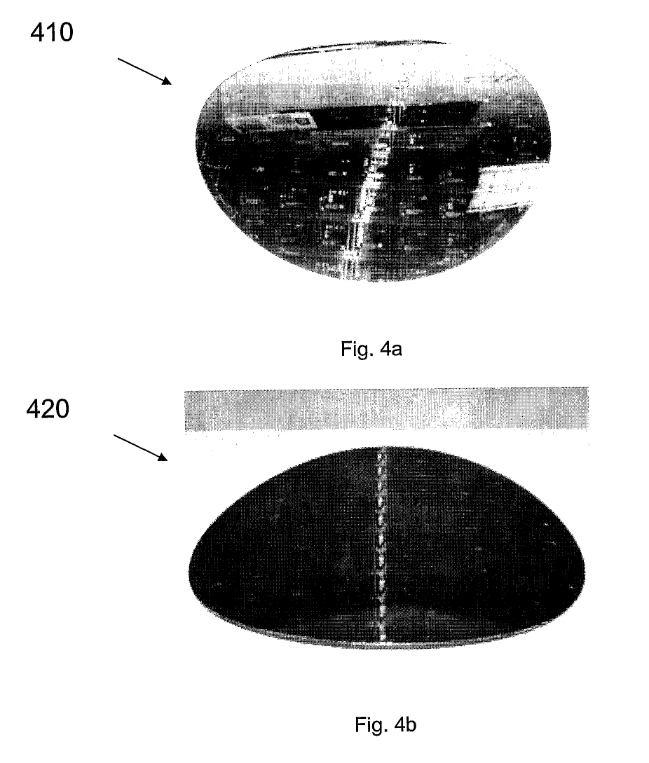

FIG. 4a and FIG. 4b show photographs of two wafer substrate units 410 and 420 produced by the method according to the first or second embodiment of the present invention and strained in horizontal direction (FIG. 4a) or in vertical direction (FIG. 4b), wherein these directions are related to the drawing plane (please note that the semiconductor wafers of both wafer substrate units are oriented identical in both photographs with respect to crystal orientation). As can be gathered from FIG. 4a and FIG. 4b, the wafer substrate units 410 and 420 have been readily produced since microelectronic device structures can be seen in these figures.

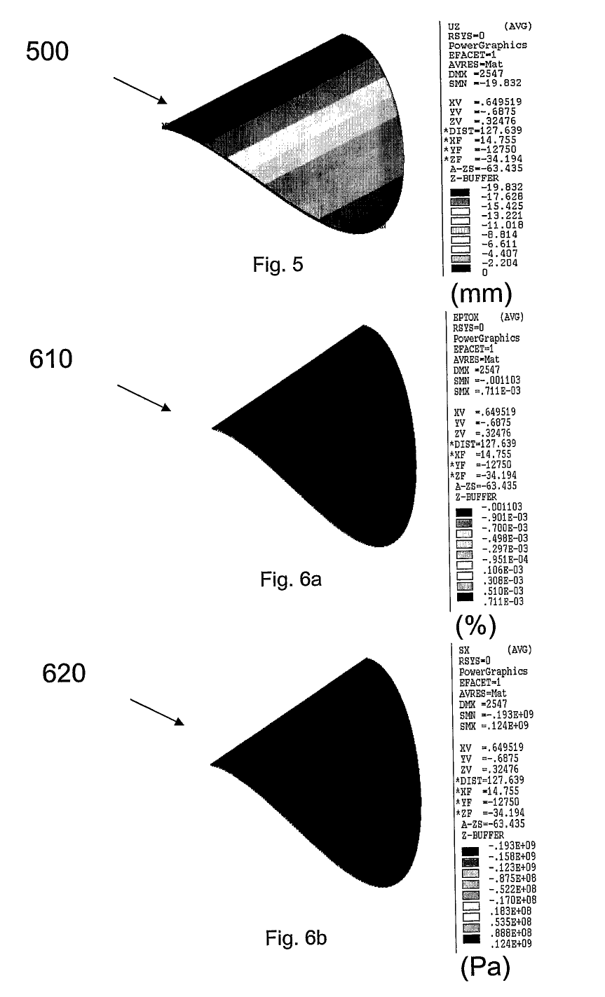

A simulation of the warpage contour 500 of a wafer substrate unit strained according to the present invention is shown in FIG. 5. This warpage contour 500 is a result from the residual stress in the wafer substrate unit due to grinding. The shown simulation gives a maximal value for the warpage contour 500 of 19.832 mm, whereas the maximal value of the warpage contour of the wafer substrate unit 420 as shown in FIG. 4b has been measured to be 20 mm.

FIG. 6a shows a simulation of the strain contour 610 and FIG. 6b shows a simulation of the stress contour 620 both of a wafer substrate unit strained according to the present invention. Accordingly, the strain contour 610 is uniform and homogeneous with a value of about 0.07% (“0.711E-03”), and the stress contour 620 shows also a uniform stress along the warpage direction with a value of about 124 MPa (“0.124E+09”). On basis of such simulations, it has been found that thinning a normal semiconductor wafer having a thickness of approximately 700 μm to a thickness of about 200 μm will increase the value of the strain by about 3 times.

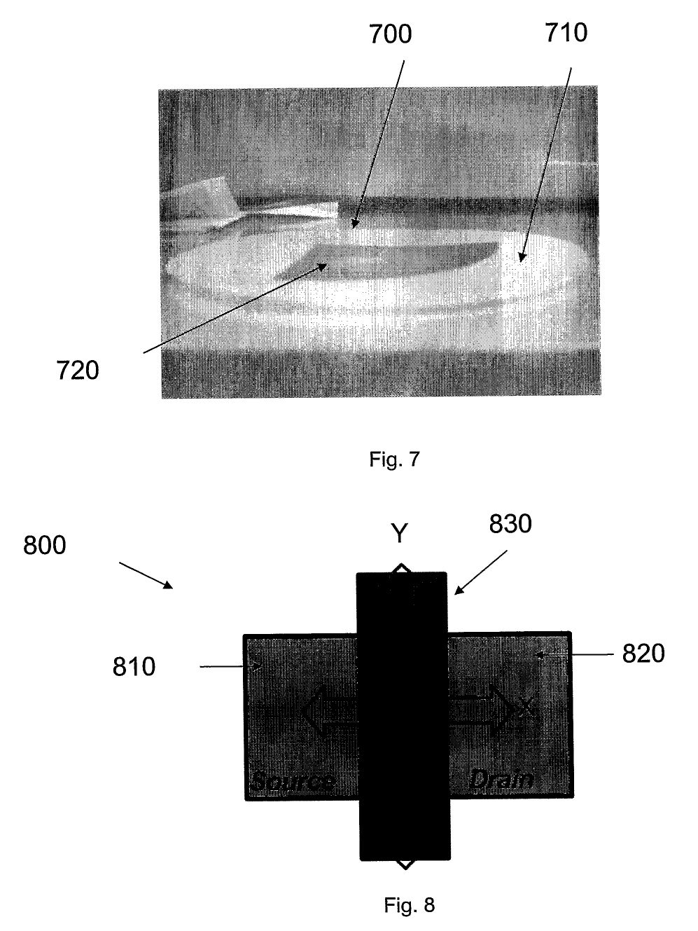

A photograph of a wafer substrate unit 700 biaxially strained according to the present invention is shown in FIG. 7. The wafer substrate unit 700 comprises a substrate 710 comprising fiberglass (FR-4) and a diameter of about 20.32 cm (8 inches). At the center, about one quarter of the substrate 710 is covered with a semiconductor wafer 720. As can be gathered from FIG. 7, the wafer substrate unit 700 is uniformly biaxially strained.

FIG. 8 shows a schematic top view onto a field-effect transistor 800 used as microelectronic device and arranged on a wafer substrate unit strained according to the present invention. The field-effect transistor 800 comprises a source 810, a drain 820 and a gate 830. Further, two of three different straining directions (X and Y) are noted in FIG. 8. In particular, the X-direction is defined by a direction from source 810 to drain 820 or vice versa and named “source drain direction”, whereas the Y-direction is defined by the longitudinal expansion of the gate 830 width, i.e. the Y-direction is perpendicular to the X-direction and parallel to the gate 830 width in same plane. Not shown in FIG. 8 is the Z-direction, which is perpendicular to the X-Y plane. With respect to FIG. 4a and FIG. 4b it is noted that the horizontal straining of the wafer substrate unit 410 is shown in FIG. 4a along the Y-direction and that the vertical straining of the wafer substrate unit 420 is shown in FIG. 4b along the X-direction.

Different directions have to be strained for different types of field-effect transistor 800 (C. Hu/VLSI Technology Symp., 2004). The performance of an N-MOSFET is enhanced by tensile straining in X- and Y-directions and by compressive straining in Z-direction, whereas the performance of a P-MOSFET is enhanced by tensile straining in Y- and Z-directions and by compressive straining in X-direction. These relations are shown for clarity in Table 1:

TABLE 1
Kind of Strain

| | N-MOSFET | P-MOSFET |
|---|---|---|
| Strain Direction | (NMOS) | (PMOS) |
| X-Direction | tensile | compressive |
| Y-Direction | tensile | tensile |
| Z-Direction | compressive | tensile |

In view of X- and Y-directions, tensile strain is needed in Y-direction for both N- and P-MOSFETs, whereas for N-MOSFETs additionally tensile strain in X-direction is needed. It is noted that no tensile strain in X-direction is needed for P-MOSFETs, but compressive strain is necessary in X-direction for P-MOSFETs. In this respect it is also noted that if two orthogonal directions are tensile strained, the third orthogonal direction must be compressive strained.

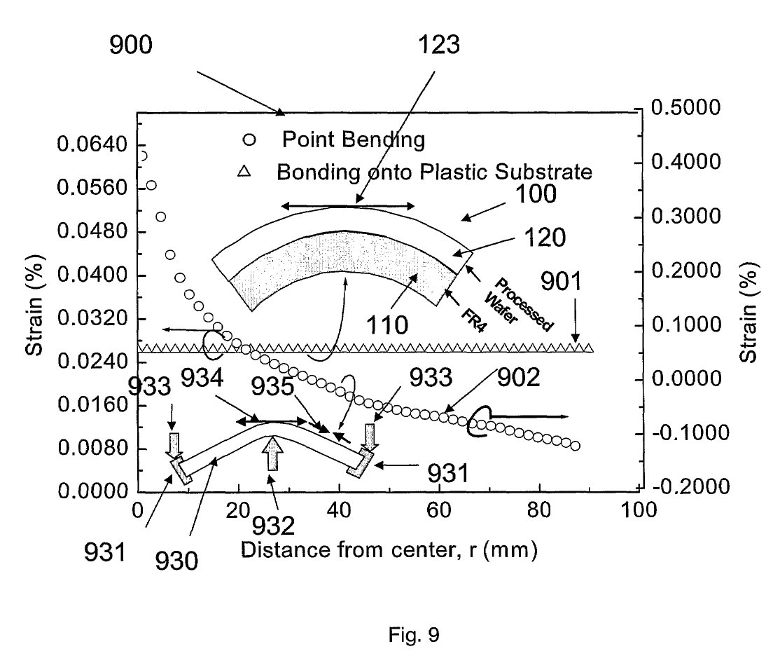

FIG. 9 shows a diagram 900 with two graphs of simulated strain to semiconductor wafers having a diameter of about 180 mm. The strain graph 901 indicated by triangles belongs to the values of a semiconductor wafer 120 strained according to the present invention and, for comparison, the strain graph 902 indicated by circles belongs to the values of a semiconductor wafer 930 strained according to the prior art. The x-axis in diagram 900 gives the distance r from the center of the respective semiconductor wafer 120 or 930 in millimeters, the right y-axis gives the strain of the semiconductor wafer 930 strained according to the prior art in percent, and the left y-axis gives the strain of the semiconductor wafer 930 strained according to the present invention in percent. As already described above in connection with FIG. 1, the wafer substrate unit 100 strained according to the present invention comprises a substrate 110 straining a semiconductor wafer 120 causing tensile strain 123. The microelectronic devices arranged on the respective semiconductor wafer are not shown in FIG. 9 for simplification. The semiconductor wafer 930 strained according to the prior art is mechanically strained by fixing the ends thereof in appropriate fixing devices 931, affecting the center of the semiconductor wafer 930 with a straining force 932 such that the ends of the semiconductor wafer 930 are affected with an opposite straining force 933 (which causes point bending of the semiconductor wafer 930) and, consequently, causing simultaneously tensile strain 934 and compressive strain 935 in the semiconductor wafer 930. As can be gathered from the strain graph 902, the strain in the semiconductor wafer 930 according to the prior art continually varies from positive values (about 0.425%) at the center to negative values (about −0.125%) at the ends of the semiconductor wafer 930. Contrary thereto, the strain graph 901 shows uniform and constant tensile strain (about 0.026%) over the whole semiconductor wafer 120 when strained according to the present invention.

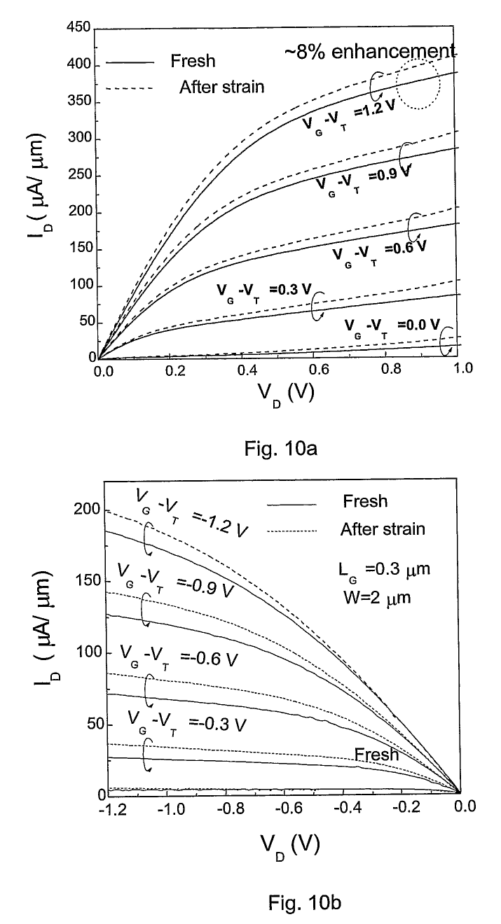

Graphical diagrams of drain current vs. drain voltage curves for a MOSFET arranged on a wafer substrate unit 100 according to the present invention are shown in FIG. 10a and FIG. 10b. In particular, FIG. 10a relates to an N-MOSFET and FIG. 10b relates to a P-MOSFET. Both graphical diagrams show curves for each two cases, one time with tensile strain mainly applied along Y-direction to the semiconductor wafer (“after strain”=broken lines) and one time without applying strain to the semiconductor wafer (“fresh”=continuous lines). The drain current ID is plotted in μA per μm, and the drain voltage V_{D} is plotted in volt. The graphical diagrams in FIG. 10a and FIG. 10b are the result of measurements for a gate length of L_{G}=0.3 μm and a gate width W=2 μm with a variation in gate voltage V_{G} corrected with threshold voltage V_{T}, i.e., V_{G}−V_{T}=±0.0 V, ±0.3 V, ±0.6 V, +0.9 V and ±1.2 V (positive values for N-MOSFET, negative values for P-MOSFET). As can be gathered from FIG. 10a and FIG. 10b, straining results in an enhancement, i.e., increase, of the drain current by between about 8% and about 10%.

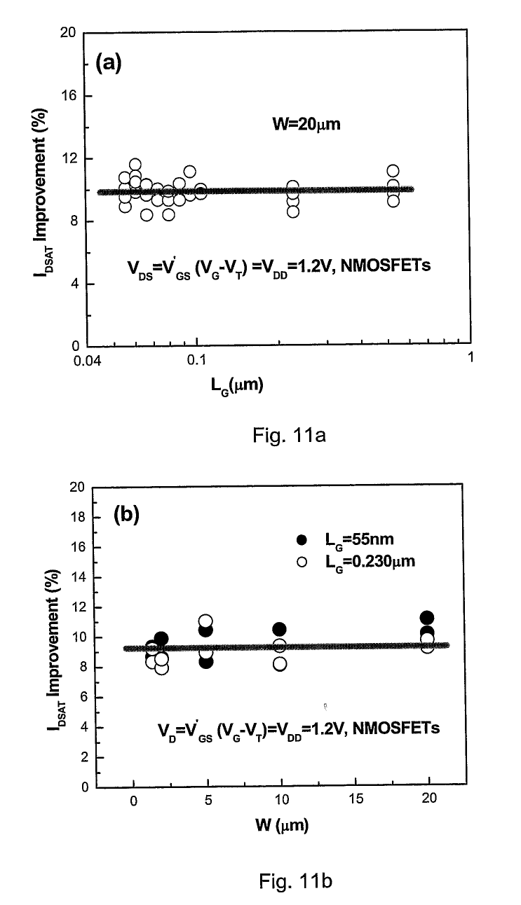

FIG. 11a shows a graphical diagram of measured improvement of saturated drain current vs. gate length for an N-MOSFET having a gate width W of 20 μm and being arranged on a wafer substrate unit strained according to the present invention. The improvement of saturated drain current I_{DSAT} Improvement is plotted in percent, and the gate length L_{G} is plotted in μm. The measurement of I_{DSAT} Improvement has been carried out at a voltage between drain and source V_{DS} of 1.2 V. It can be gathered from FIG. 11a that I_{DSAT} Improvement is very stable at a value of about 10% for gate lengths in the range of between about 0.05 μm and about 0.55 μm.

FIG. 11b shows a graphical diagram of measured improvement of saturated drain current vs. gate width for N-MOSFETs with gate lengths L_{G} of 0.23 μm and 55 nm arranged on a wafer substrate unit strained according to the present invention. Like in FIG. 11a, the improvement of saturated drain current I_{DSAT} Improvement is plotted in percent, and the gate width W is plotted in μm. The measurement of I_{DSAT} Improvement has been carried out at a voltage between drain and source V_{DS} of 1.2 V. It can be gathered from FIG. 11b that I_{DSAT} Improvement is also very stable at a value of about 9.5% for gate widths in the range of between about 2 μm and about 20 μm. Therefore the improvement of saturated drain current is free of dimensional dependence in either gate length or width.

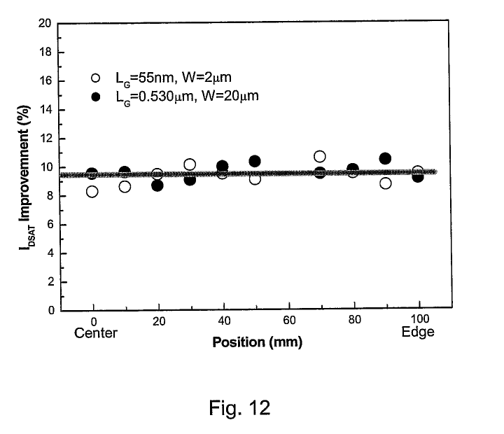

A graphical diagram of measured improvement of saturated drain current vs. position on the semiconductor wafer for two N-MOSFETs arranged on a wafer substrate unit strained according to the present invention is shown in FIG. 12. The two N-MOSFETs have different gate lengths and gate widths, in particular, one has a gate length L_{G} of 55 nm and a gate width W of 2 μm, whereas the other has a gate length L_{G} of 0.53 μm and a gate width W of 20 μm. The improvement of saturated drain current I_{DSAT} Improvement is plotted in percent, and the position on the semiconductor wafer is plotted in mm from the center at 0 mm to the edge at 100 mm. As can be gathered from FIG. 12, the I_{DSAT} Improvement is uniform across the whole wafer, is independent of the gate length and width, and has a value of about 9.5%. An I_{DSAT} improvement of about 7% is also observed for P-MOSFETs. Furthermore, the improvement is completely preserved in devices in individual dies after dicing.

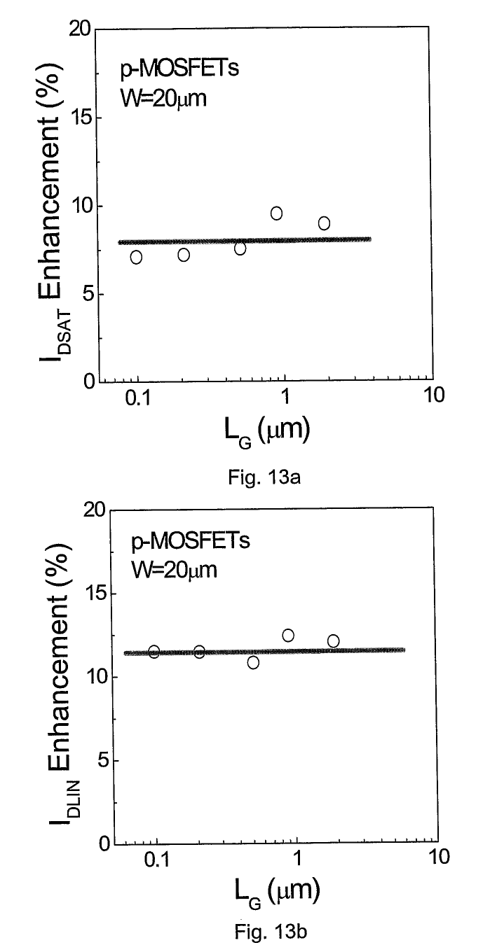

FIG. 13a shows a graphical diagram of enhancement of saturated drain current vs. gate length for a P-MOSFET with gate width W of 20 μm and being arranged on a wafer substrate unit strained according to the present invention. The enhancement of saturated drain current I_{DSAT} enhancement is plotted in percent, and the gate length L_{G} is plotted in μm. Similar to n-MOSFET in FIG. 11a, the I_{DSAT} enhancement as gathered from FIG. 13a is very stable at a value of about 8% for gate lengths in the range of between about 0.05 μm and about 4 μm.

FIG. 13b shows a graphical diagram of enhancement of linear mode drain current vs. gate length for a P-MOSFET with gate length W of 20 μm and being arranged on a wafer substrate unit strained according to the present invention. The enhancement of linear mode drain current I_{DLIN} enhancement is plotted in percent, and the gate length L_{G} is plotted in μm. It can be gathered from FIG. 13b that I_{DSAT} enhancement is very stable at a value of about 11.5% for gate lengths in the range of between about 0.05 μm and about 6 μm.

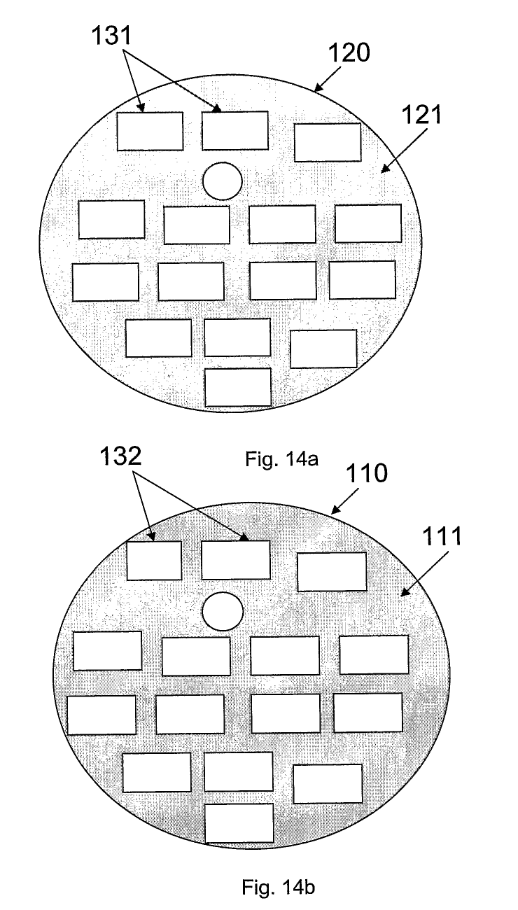

FIG. 14a shows a schematic top view of a semiconductor wafer patterned on the backside or first wafer surface 121 of the semiconductor wafer 120, where respective cavities or contact shapes 131 are made. The depth of the cavities are approximately about 200 μm. Preferential strain is induced through different contact shapes with the substrate or bonding material. Due to the patterned surface of the semiconductor backside, only certain areas will be bonded with the substrate material. Patterning can be used to engineered preferential strain on selective dies.

FIG. 14b shows a schematic top view of a substrate 110 patterned on the substrate surface 111, where respective cavities or contact shapes 132 are made. The depth of the cavities is approximately about 200 μm. Similarly, preferential strain is induced through different contact shapes with the substrate or bonding material. Due to the patterned surface of the semiconductor backside, only certain areas will be bonded with the substrate material. Patterning can be used to engineered preferential strain on selective dies.

It should be mentioned that there exists also the possibility to cover the interface of the semiconductor wafer, where the microelectronic devices are integrated at, with substrate material for straining the semiconductor wafer by the deposited substrate material (known as “topside coating”). For improvement of dissipation of heat generated from the microelectronic devices during operation. The above described “backside coating” can be used, i.e. the adhering of the substrate (material) to the semiconductor wafer on an interface of the semiconductor wafer which is opposite to the microelectronic devices.

The present invention can be further improved and made even more reliable by using substrate materials having larger thermal expansion coefficients than the semiconductor wafer such as silicon nitride (SiN). Such an embodiment may be useful if a strained semiconductor wafer of the present invention is to be operated in a wide temperature range, e.g., from about −5° C. to about 125° C. as required for military application, for example.

Although this invention has been described in terms of illustrative embodiments, it has to be understood that numerous variations and modifications may be made, without departing from the spirit and scope of this invention as set out in the following claims.

1. A method for straining a semiconductor wafer, the method comprising:
providing a semiconductor wafer, the semiconductor wafer having a first wafer surface and a second wafer surface arranged substantially opposite the first wafer surface;
providing a substrate, the substrate having a substrate surface;
adhering the first wafer surface to the substrate surface, thereby connecting the semiconductor wafer to the substrate and forming a wafer substrate unit;
heating the semiconductor wafer and the substrate to a first temperature; and
cooling the wafer substrate unit to a second temperature lower than the first temperature;
thereby straining and bending the semiconductor wafer.

2. The method of claim 1, further comprising providing the semiconductor wafer having a first thermal expansion coefficient and providing the substrate having a second thermal expansion coefficient.

3. The method of claim 2, further comprising using materials for the semiconductor wafer and the substrate such that the second thermal expansion coefficient is greater than the first thermal expansion coefficient.

4. The method of claim 1, wherein adhering the first wafer surface to the substrate surface comprises the step of bonding the first wafer surface onto the substrate surface.

5. The method of claim 1, wherein providing the substrate and adhering the first wafer surface to the substrate surface are carried out in a single step by depositing the substrate onto the first wafer surface.

6. The method of claim 5, wherein depositing the substrate is carried out by chemical vapor deposition.

7. The method of claim 6, wherein depositing the substrate is carried out by plasma-enhanced chemical vapor deposition.

8. The method of claim 5, wherein depositing the substrate is carried out by sputtering.

9. The method of claim 1, wherein the substrate is tensile strained.

10. The method of claim 1, wherein the substrate is compressive strained.

11. The method of claim 1, wherein the semiconductor wafer is strained uniaxially or biaxially.

12. The method of claim 1, wherein the semiconductor wafer comprises a plurality of microelectronic devices at the second wafer surface.

13. The method of claim 12, wherein the microelectronic devices comprises metal-oxide semiconductor field-effect transistors.

14. The method of claim 13, wherein the metal-oxide semiconductor field-effect transistors comprises at least one N-MOSFET and/or one P-MOSFET.

15. The method of claim 13, wherein each metal-oxide semiconductor field-effect transistor comprises a source, a drain and a gate, wherein the gate is arranged between the source and the drain.

16. The method of claim 15, wherein the tensile strain in the semiconductor wafer is in a direction perpendicular to source-drain and parallel to gate.

17. The method of claim 15, wherein the tensile stain in the semiconductor wafer is in source-drain direction.

18. The method of claim 1, wherein providing the semiconductor wafer comprises thinning the semiconductor wafer.

19. The method of claim 18, wherein thinning the semiconductor wafer comprises thinning the semiconductor wafer to a thickness of about 200 μm.

20. The method of claim 1, wherein providing the semiconductor wafer comprises forming the semiconductor wafer out of a material selected from the group consisting of silicon, poly-silicon, gallium arsenide, germanium and silicon-germanium.

21. The method of claim 1, wherein providing the semiconductor wafer comprises providing the semiconductor wafer with a diameter of between about 20.32 cm (8 inches) to about 30.48 cm (12 inches).

22. The method of claim 1, wherein the substrate comprises a material selected from the group consisting of fiberglass, laminate material, polymeric material, silicon nitride and titanium nitride.

23. The method of claim 1, wherein the first temperature is between about 120° C. and about 400° C.

24. The method of claim 23, wherein the first temperature is between about 160° C. and about 200° C.

25. The method of claim 1, wherein the second temperature is about ambient temperature.

26. The method of claim 1, wherein providing the substrate comprises patterning the substrate at the substrate surface.

27. The method of claim 26, wherein patterning the substrate comprises wet-etching the substrate after production of the substrate, or shadow masking during the production of the substrate.

28. The method of claim 27, wherein shadow masking during the production of the substrate comprises sputtering substrate material through a shadow mask.

29. The method of claim 28, wherein sputtering substrate material comprises sputtering the substrate material at different powers for adjusting material density and, thus, for obtaining a tensile strained substrate or a compressive strained substrate.

30. The method of claim 26, wherein patterning the substrate comprises one- or two-dimensionally patterning the substrate stripe alike.

31. The method of claim 1, wherein providing the semiconductor wafer comprises patterning the semiconductor wafer at the first wafer surface.

32. A wafer substrate unit comprising a semiconductor wafer and a substrate, wherein:
the semiconductor wafer has a first wafer surface, a second wafer surface arranged substantially opposite the first wafer surface;
the substrate has a substrate surface;
the first wafer surface is adhered to the substrate surface such that the semiconductor wafer is connected to the substrate; and
the substrate strains the semiconductor wafer such that the semiconductor wafer is bent.

33. The wafer substrate unit of claim 32, wherein the substrate strains the semiconductor wafer uniaxial or biaxial.

34. The wafer substrate unit of claim 32, wherein the substrate tensile strains the semiconductor wafer.

35. The wafer substrate unit of claim 32, wherein the substrate compressive strains the semiconductor wafer.

36. The wafer substrate unit of claim 32, further comprising a plurality of microelectronic devices at the second wafer surface of the semiconductor wafer.

37. The wafer substrate unit of claim 36, wherein the plurality of microelectronic devices comprises a plurality of metal-oxide semiconductor field-effect transistors.

38. The wafer substrate unit of claim 37, wherein the plurality of metal-oxide semiconductor field-effect transistors comprises at least one N-MOSFET and/or one P-MOSFET.
